(19) United States
(12) Patent Application Publication
(10) Pub. No.: US 2004/0038436 A1
(43) Pub. Date: Feb. 26, 2004

(54) Method of manufacturing a semiconductor integrated circuit device

(75) Inventors: Masahito Mori, Tokorozawa (JP); Takashi Tsutsumi, Kawasaki (JP); Masaru Izawa, Hino (JP); Naoshi Itabashi, Hachioji (JP)

Correspondence Address: Miles & Stockbridge P.C., Suite 500, 1751 Pinnacle Drive, McLean, VA, 22102-3833, US

(73) Assignees: Hitachi, Ltd.; Hitachi High-Technologies Corporation

(21) Appl. No.: 10/247,523

(22) Filed: Sep. 20, 2002

(30) Foreign Application Priority Data
Aug. 9, 2002 (JP) 2002-232246

(51) Int. Cl. H01L 21/302; H01L 21/461; H01L 21/3205; H01L 21/4763; G01R 31/26; H01L 21/66

(52) U.S. Cl. 438/17; 438/585; 438/719; 438/720

(57) ABSTRACT

Disclosed is a method of manufacturing a semiconductor integrated circuit device which will not incur an increase in chip cost and a reduction in throughput, wherein the method includes a step of patterning a gate (electrode or wiring). With the method, a hard mask on the gate is patterned by a resist mask, and then the resist mask is removed. The gate material side surface is trimmed by using the hard mask under such dry etching conditions that no reaction product will be left on the gate material side surface to form an I-type gate.

### BACKGROUND OF THE INVENTION

1. Field of the Invention

The present invention relates to a method of manufacturing a semiconductor integrated circuit device. More particularly, it relates to a method of manufacturing a semiconductor integrated circuit device, whereby a gate electrode of CMOS with a length of not more than 50 nm which is beyond the limit of lithography resolution is mass produced in a high yield.

2. Description of the Related Art

Among semiconductor integrated circuit devices, there are memories typified by a DRAM and the like, and logic LSIs or system LSIs typified by a microprocessor (MPU). The processes for fabricating a semiconductor integrated circuit device (LSI) include the formation of a gate electrode. This process generally includes: a step of forming a gate insulating film and a gate electrode film; a mask formation step of transferring a circuit pattern to a mask layer; a gate etching step of processing the gate electrode film by etching; an ashing step of removing a resist and a residual halogen gas; and a cleaning step of removing foreign matters and deteriorated matters resulting from etching. After the formation of the gate electrode, the process goes through a source/drain formation step, and proceeds to a contact formation step.

Due to a demand for lower power consumption and higher speed of the semiconductor integrated circuit device (LSI), the device is decreasing in size year after year. ITRS (International Technology Roadmap for Semiconductor), 2000 (SC.2) clearly states that the technology node (T.N) will be reduced more than that shown in the previous issue, as shown in Table 1. Namely, as the processing technology required for reducing the size of the LSI, mention may be made of a technology of trimming the gate length (gate dimension along the channel length).

TABLE 1

| | 1999 | 2000 | 2001 | 2002 | 2003 | 2004 | 2005 |
|---|---|---|---|---|---|---|---|
| TN | 180 nm | | | 130 | | | 100 |
| 1999 issue | | | | | | | |
| TN | 180 nm | | 130 | | 100 | | |
| 2000 (S.C2) | | | | | | | |
| MPU gate length | | | 90 | | 70 | | |
| 2000 (S.C2) | | | | | | | |
| MPU gate length | 130 nm | | 70 | | 50 | | 35 |
| advanced | | | | | | | |
| manufacturers | | | | | | | |

Incidentally, the technologies associated with trimming of the gate length are disclosed in, for example, (1) Japanese Published Unexamined Patent Application No. 136402/1993; (2) Japanese Published Unexamined Patent Application No.209018/1994; (3) 2000 DRY PROCESS SYMPOSIUM p.121-P.125; (4) Extended Abstracts (The 48th Spring Meeting, 2001. 3) 30p-YE-10, p.776; The Japan Society of Applied Physics and Related Societies; and the like.

The study on gate trimming conducted by the present inventors for completing the present invention will be described below by reference to accompanying drawings.

In the mask formation step, for a 0. 18-mm design rule, an exposure system including ultrahigh resolution means such as a KrF laser (248 nm in wavelength) and a phase-shift mask is used, and a multi-layer mask structure having a resist and the underlying antireflection film is essential. For the antireflection films, two types: an organic antireflection film (BARC: Bottom Anti-Reflection Coating) and an inorganic antireflection film (BARL: Bottom Anti-Reflection layer or SiON: silicon oxinitride) are used. Whereas, the use of an ArF excimer laser (193 nm in wavelength) is examined as a next-generation exposure light source adaptable to not more than 0.10 mm.

For dry etching employed for the mask formation step and the gate etching step, there is widely used a method in which a reactant gas is changed into plasma in a vacuum chamber, and the ion assisted reaction is utilized. A plasma is generated in the following manner. A gas for etching introduced into a vacuum chamber is irradiated with an electromagnetic wave. The gas is dissociated by the energy. The plasma generation modes are classified according to the mode of interaction between the electromagnetic wave and the plasma. Typical plasma sources include capacitive coupled plasma (CCP), inductive coupled plasma (ICP), and electron cyclotron resonance (ECR) plasma sources. The electromagnetic wave used for CCP, ICP, or ECR has a frequency of 13.56 MHz or 27 MHz. For ECR, a microwave of 2.45 GHz or a UHF wave of 450 MHz or the like is used.

With such a dry etching apparatus, the processing geometry is controlled by adjusting the following apparatus parameters: the species of etchant gas, the processing pressure, and the power of electromagnetic wave, which determine the characteristics of plasma; the sample setting temperature which determines the characteristics of chemical reactions; the power of RF bias to draw ions to the sample; and the like. The etchant gas used for this step is implemented by selecting an appropriate gas according to the type of a film to be etched. For example, for BARC etching employed in the mask formation step, a gas obtained by adding Cl₂, CF₄, or N₂ to O₂, or adding Ar as a diluting gas thereto is used. Whereas, for BARL or SiO₂ etching, a gas obtained by diluting a fluorocarbon gas such as C₄F₈ or C₅F₈ with O₂ and a gas obtained by diluting CO with Ar are used. As for gate electrode etching, a gas obtained by adding Cl₂, N₂, and O₂ to CF₄ or SF₆ is used for a W or WSi layer, and a gas obtained by adding O₂ or He to CF₄, Cl₂, HBr, or NF₃ is used for a poly-Si layer.

In the gate etching step, the dimension at the lower part of the gate, i.e., the gate length is the primary factor for determining the device characteristics. Therefore, a high precision dimension controllability of not more than 3s10% is required. This necessitates that the dimensional shift from the mask dimension (CD shift, CD: Critical Dimension) is controlled to the minimum, i.e., the gate is etched as vertically as possible.

Whereas, as shown in Table 1 above, the gate electrode is being reduced in size year by year due to the demand for a lower consumption power and a higher speed. Further, advanced semiconductor manufacturers are promoting the implementation of this road map, and aim to ship new products with a gate length of 50 nm in 2003.

FIGS. 7 and 8 respectively show changes in decreasing gate length and exposure dimension based on the study by the present inventors.

Referring to FIG. 7, in 2003, a gate length 702 of a product (ex., MPU) is required to be 50 nm for an exposure dimension 701 of 100 nm, so that the gate length is required to be reduced by 50 nm than the exposure dimension 701. The exposure dimension 701 in 2003 and afterward is the dimension based on an exposure technology using an ArF laser (193 nm in wavelength). At present, however, there is another possibility that the gate is trimmed in length from an exposure dimension of 180 nm by a KrF laser because of problems with the exposure characteristics and apparatus cost, including resist materials.

FIG. 8 shows changes in resist film thickness required for implementing the gate dimension processing shown in FIG. 7. Particularly, a line 804 indicates changes in the resist film thickness required for exposure, while a line 805 indicates changes in resist film thickness (residual film thickness) after BARC etching.

As revealed from FIGS. 7 and 8, for example, for resolution of a 100-nm exposure dimension (in 2003), the resist film thickness is required to be reduced to not more than 300 nm as shown in FIG. 8. This is due to the fact that the resist film thickness needs to be roughly about not more than 3 times the resolution dimension as a guide for avoiding the destruction of the resist pattern due to the surface tension of the developer after exposure.

On the other hand, the thickness of the antireflection coating film (BARC) remains unchanged along its thickness even though miniatuarization of the gate length proceeds, because it is univocally determined by its absorption coefficient and the transmittance with respect to the wavelength of the light source. Likewise, for the necessary thickness of the gate electrode, the gate electrode will have a limit to reduction in its thickness, which is about 100 nm. This is for avoiding the following problems: reduction in voltage for dopant implantation is limited and there is a possibility of dopant penetrating the gate insulating film due to heat diffusion.

As described above, for processing of a gate, whose reduction in length have been under way, as shown in FIG. 8, although the resist film thickness 804 necessary for exposure decreases, the film to be etched (BARC, BARL, hard mask, or gate electrode) does not change in thickness very much. Accordingly, in 2003 and afterward, the resist residual film thickness 805 after trimming of the mask is smaller than the mask film thickness 803 necessary for etching of BARC, BARL, hard mask, poly-Si, or the like. This reveals that the gate electrode cannot be trimmed in length (gate length cannot be reduced) only by trimming of the mask.

When a gate with a smaller length than the mask dimension is formed, unfavorably, the chip cost increases due to an increase in number of process steps, and the total throughput decreases.

Further, for example, when a gate electrode is processed in T form or in notch form as disclosed in the aforesaid known publication (2), (3), or (4), the dimension inspection after gate processing cannot be applied. Namely, even if the gate is observed from above the gate, it is not possible to determine the proper gate length (the gate length in contact with a gate oxide film). Therefore, no step can be taken for a variation in gate dimension due to a change with time. The variation in gate dimension causes the characteristics of the device to vary, unfavorably resulting in a reduction in yield, or a reduction in throughput due to the device cleaning.

When a dimension inspection is carried out on a T-type or notch-type gate, a novel method (scatterometry, electric resistance measuring machine, or the like) is conceivable. However, the purchase of the new device incurs another cost.

### SUMMARY OF THE INVENTION

In view of the foregoing, it is therefore an object of the present invention to provide a method of manufacturing a semiconductor integrated circuit device, the method including a step of forming a fine pattern, which will not incur an increase in chip cost and a reduction in throughput.

It is another object of the present invention to provide a method of manufacturing a semiconductor integrated circuit device, which is capable of improving the yield and throughput.

In accordance with one aspect of the present invention, a method of manufacturing a semiconductor integrated circuit device is characterized by including the steps of: for patterning a gate (electrode or wiring), patterning a hard mask by a resist mask, and then removing the resist mask; and trimming the gate material side surface by using the hard mask under such dry etching conditions that no reaction products remain on the gate material side surface to form an I type gate.

Other and further objects, features and advantages of the invention will appear more fully from the following description.

### BRIEF DESCRIPTION OF THE DRAWINGS

FIG. 1A is a schematic diagram showing a process flow in accordance with Embodiment 1 of the present invention, and FIG. 1B is a cross sectional view showing the process of forming an I-type gate in accordance with Embodiment 1 of the present invention;

FIGS. 2A to 2G are cross sectional views showing a manufacturing process of a semiconductor integrated circuit device in accordance with Embodiment 1 of the present invention;

FIG. 3 is a diagram showing a principal configuration of an UHF-ECR plasma etching apparatus to be used for manufacturing the semiconductor integrated circuit device in accordance with Embodiment 1 of the present invention;

FIGS. 4A to 4E are cross sectional views showing a manufacturing process of a semiconductor integrated circuit device in accordance with Embodiment 4 of the present invention;

FIGS. 5A and 5B are cross sectional views showing a manufacturing process of the semiconductor integrated circuit device, following the steps of FIGS. 2A to 2G;

FIG. 6 is a cross sectional view showing a manufacturing process of a semiconductor integrated circuit device, which is another application example of the present invention;

FIG. 7 is a graph showing the changes in decreasing gate length and exposure dimension;

FIG. 8 is a graph showing the changes in resist film thickness necessary for implementing gate dimension processing; and

FIG. 9 is a graph showing the changes in boiling point of a Si reaction product in each halogen with respect to the valence of H.

### DETAILED DESCRIPTION OF THE PREFERRED EMBODIMENTS

(Embodiment 1)

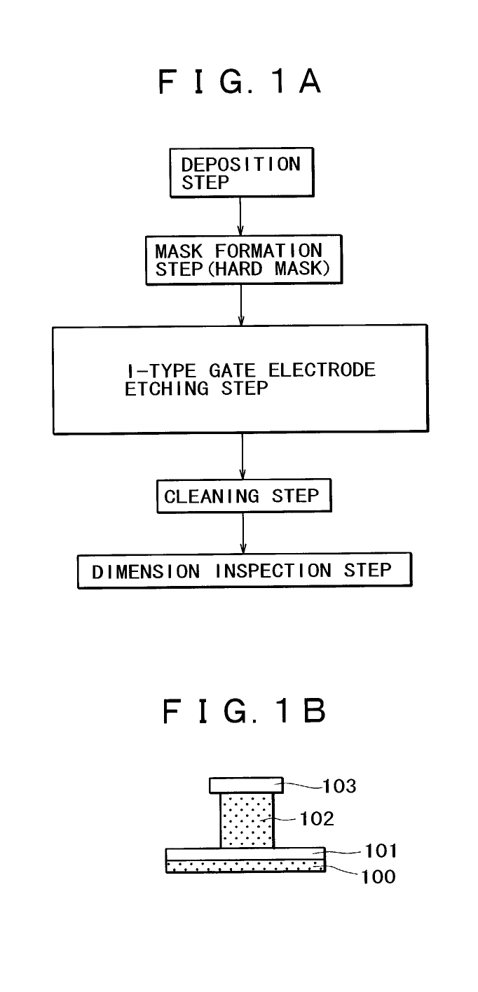

FIG. 1A shows a schematic diagram of a process flow for forming an I-type gate in accordance with the present invention. Whereas, FIG. 1B is a cross sectional view showing the process of forming the I-type gate using a hard mask. In FIG. 1B, a gate insulating film 101 is formed on the primary surface of a Si substrate (wafer) 100. On the gate insulating film 101, a gate electrode 102 is trimmed along its overall sidewall by using a hard mask 103. The trimming will be described in detail later.

Incidentally, in a Si gate vertical etching technology, in general, a sidewall protective film (reaction product) is formed on the sidewall of the gate during etching. For this reason, it is considered difficult to trim the I-type gate unless the number of processes is increased. The composition of the sidewall protective film is made up of a Si oxide such as SiOₓ, and reaction products such as SiClₓ and SiBrₓ. Therefore, for avoiding the formation of the sidewall protective film, O₂ is not added, or the volatility of the reaction product is improved in the main etching step for performing gate processing.

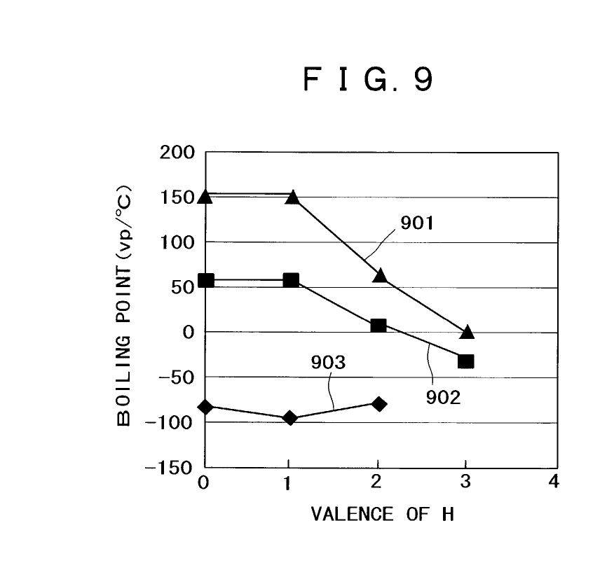

FIG. 9 is a graph showing how the boiling point 901 of SiHₓBr(₄₋ₓ), the boiling point 902 of SiSiHₓCI(₄₋ₓ), and the boiling point 903 of SiHₓF(₄₋ₓ) change according to the valence of H. As indicated from the graph, the boiling point decreases, i.e., the volatility increases in the order of SiBr, SiCl, and SiF, and the volatility increases with an increase in valence of H. Therefore, formation of a high-volatility Si reaction product can be accomplished by using a F-containing gas, or a gas obtained by appropriately adding H to Cl or Br.

With the foregoing process whereby no sidewall protective film is formed, the underlayer selectivity is low. Therefore, when not less than 50-nm trimming is performed, another trimming step is required in addition to the foregoing process. In order to perform trimming without causing the underlayer loss, the selection ratio of the etching rate relative to that of the gate insulating film is required to be not less than 200. Incidentally, the underlayer is made up of a SiO₂ film as the gate insulating film.

The present inventors discovered another trimming step whereby a high underlayer selectivity is ensured. When the underlayer selectivity is ensured without adding O₂ as in the present invention, an RF bias of 0 W (zero Watt), i.e., spontaneous etching may be applied.

Table 2 shows measurement results of each spontaneous etching rate in Cl₂ and HCl gases. As indicated, when a HCl gas is used at a RF bias of 0 W, although the SiO₂ etching rate is 0 nm/min, the poly-Si etching rate is 51.7 nm/min, which is 5 times as fast as in Cl₂. Accordingly, trimming can be achieved in a shorter time, which is advantageous in terms of underlayer selectivity.

TABLE 2

| | Cl₂ | HCl |
|---|---|---|
| PolySi | 10.4 nm/min | 51.7 nm/min |
| SiO₂ | 0 nm/min | 0 nm/min |

The results are attributable to the fact that the volatility of the Si reaction product increases due to the inclusion of H as shown in FIG. 9.

The foregoing results indicate as follows. By effecting spontaneous etching with a H-containing gas as a trimming step, it is possible to implement not less than 50-nm trimming without causing the underlayer loss.

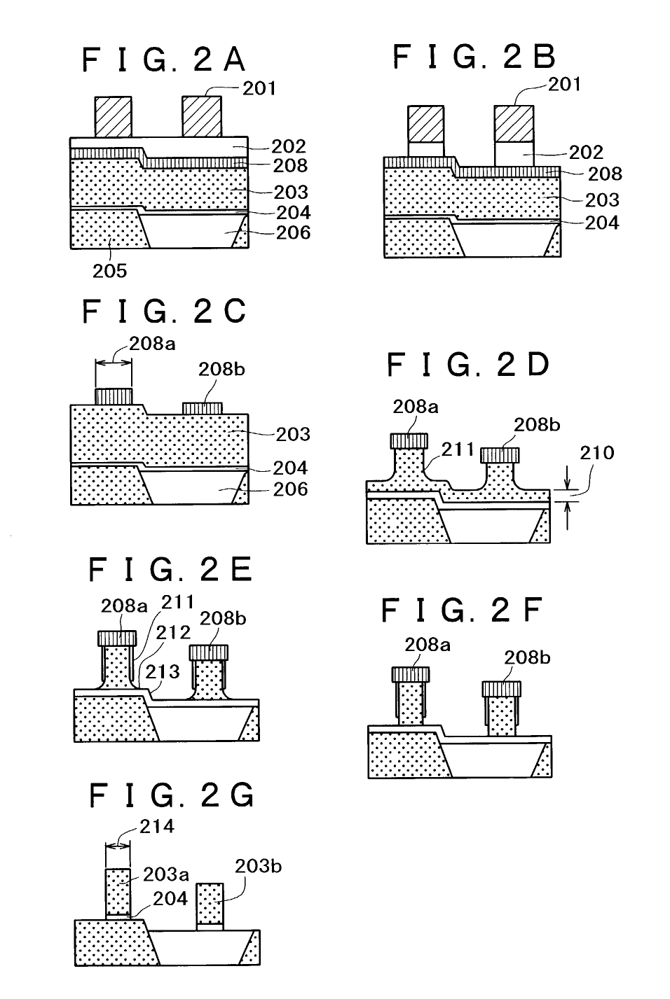

Below, a description will be given to an embodiment wherein an I-type gate with a gate length of 50 nm or less is obtained by reference to FIGS. 2A to 2G. The gate electrode formation step follows the basic constitution of the present invention shown in FIG. 1. Particularly, this embodiment shown in FIGS. 2A to 2G pertains to a method for performing gate processing by means of a mask (hard mask) using no organic matter. It is noted that the wafer applied for carrying out the method is an 8-inch wafer.

First, FIG. 2A is a cross sectional view showing the manufacturing process of a semiconductor integrated circuit device immediately after the completion of exposure whereby a resist mask has been patterned in a prescribed circuit pattern. In FIG. 2A, a shallow trench isolation (STI) 206 for element isolation is selectively formed in a Si substrate 205. On the surface of the Si substrate 205 sectioned by the STI 206, a SiO₂ film 204 with a thickness of not more than 10 nm as the gate insulating film is formed by thermal oxidation. On the SiO₂ film 204, a poly-Si layer 203 to be a gate electrode is formed by a CVD process. On the poly-Si layer 203, an insulating film 208 for a hard mask is formed. By using the hard mask, it is possible to improve the dimensional precision at the time of gate processing, and the selectivity with respect to the gate insulating film (thermal oxide film). As the hard mask materials, “TEOS” (Tetraethyl orthosilicate) for an inorganic insulating film, a SiO₂ film by HLD (high temperature low pressure decomposition), or the like, and a SiN film are selected. In this step, a TEOS film 208 is formed as one example. On the TEOS film 208, a BARC 202 serving as an antireflection film is formed by spin coating. Since the BARC 202 is formed by spin coating, its principal surface is a flat surface. Then, on the principal surface of the BARC 202, a resist mask 201 is patterned by means of a general photolithography technique.

Subsequently, as shown in FIG. 2B, the BARC 202 and the TEOS film 208 are etched, so that the pattern of the resist 201 is transferred to the TEOS film 208.

Then, as shown in FIG. 2C, the resist 201 and the BARC 202 are removed by ashing.

To the ashing step, a method utilizing ICP or a microwave plasma, or a method utilizing O₃ generated under normal pressure is applied. When a plasma is utilized, a fluorocarbon gas such as CF₄ or CHF₃ or a H₂/N₂ reducing gas may be added to O₂ for the purpose of increasing the resist reaction rate.

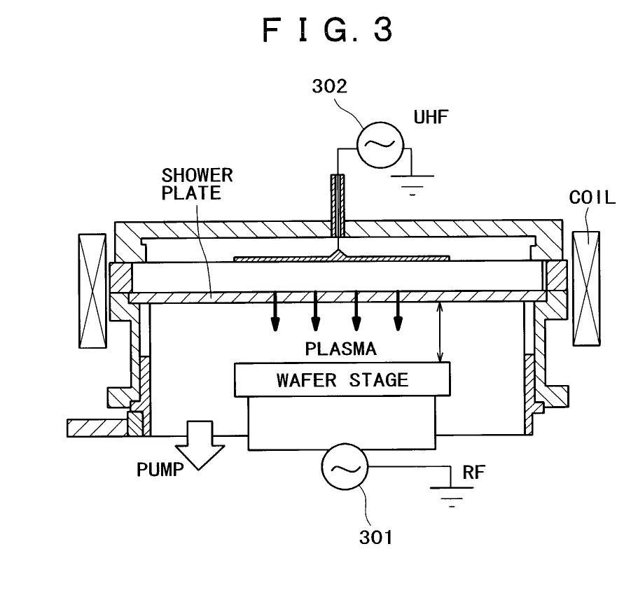

Subsequently, an I-type gate (electrode) is formed using the TEOS 208a and 208b onto which the pattern has been transferred as a mask by means of an UHF-ECR plasma etching apparatus by the following steps. Incidentally, the main configuration of the UHF-ECR plasma etching apparatus to be used in this embodiment is shown in FIG. 3.

First, In a ME1 (Main Etch1) step, the poly-Si material 203 is vertically etched in a Cl₂ gas plasma added with 3% SF₆ at a RF bias (301) of 40 W and an UHF power (302) of 500 W. In this step, the amount of O₂ to be added is 0 cc. Namely, by not adding O₂, a sidewall protective film is prevented from being deposited on the sidewall of the poly-Si material 202 formed by etching. Since no sidewall protective film is deposited thereon, the fluorine of SF₆ reacts with the Si material of the sidewall, so that side etching proceeds. Further, since a RF bias is applied to the wafer, the side-etched sidewall can obtain verticality. FIG. 2D shows the cross sectional profile immediately after switching from the ME1 step to the subsequent ME2 (Main Etch 2) step at a time point such that the residual film thickness 211 of the poly-Si material 202 on the gate oxide film 204 is 30 nm. Thus, O₂ is not added, so that the sidewall protective film, which occurred in prior art, is not formed. As a result, it is possible to obtain the sidewall 211 trimmed by 25 nm per side.

Then, in the ME2 (Main Etch 2) step, a gas added with 3% O₂ is used. The reason for adding O₂ in the vicinity of the underlying gate insulating film (thermal oxide film) 204 is to ensure the selectivity of the gate insulating film 204 and the poly-Si material 203. FIG. 2E is a cross sectional profile immediately after performing the end point determination in the ME2 step. The sidewall protective film 211 made up of a material based on an oxide such as SiOₓ or a material based on reaction products such as SiClₓ and SiBrₓ is formed due to added O₂, so that trimming is stopped. Further, there are a tail 212 in the vicinity of the interface with the gate insulating film 204, and an etch residue 213 at the step portion generated in the STI (shallow trench isolation) 206 formation step.

After the completion of the ME2 step, an OE (Over Etch) step is performed in a conventional Cl₂/O₂ or HBr/O₂ gas, or a diluting gas such as Ar or He to remove the tail 212 in the vicinity of the interface with the gate insulating film 204 and the etch residue 213 at the step portion. As a result, it is possible to obtain the vertical shape as shown in FIG. 2F.

After the completion of gate etching by the foregoing steps, the TEOS mask 208a and 208b is removed by a HF solution. As a result, it is possible to obtain a gate electrode having a dimension 214 more reduced than the exposure dimension as shown in FIG. 2G. In addition, the dimension of the bottom face of the gate electrode 203a (203b) in contact with the gate insulating film 204 is roughly equal to the dimension (214) of the upper part of the gate electrode 203a (203b). Namely, an I-type gate is implemented.

Subsequently, in a cleaning step for removing the foreign matters and contaminants in the etching step, a wet cleaning using a solution is performed. As the solution, a NH₄OH/H₂O₂ or HCl/H₂O₂ aqueous solution, or a HF solution is used. The solution is used by adjusting the mixing ratio, time, solution temperature, and the like according to the type of generated contamination. The HF solution to be used is capable of selectively removing a hard mask of SiO type with respect to Si.

Thereafter, the I-type gate shown in FIG. 2G is inspected for the gate dimension. The shape shown in FIG. 2G is inspected by a critical dimension scanning electron microscopy commonly used in the manufacturing process of a semiconductor integrated circuit device, suitable for the in-line pattern measurement. In this inspection step, the dimension is determined from above the wafer by means of the critical dimension scanning electron microscopy. The wafer is placed in vacuum as it is, and scanned by an electron beam on the wafer principal surface, which enables a nondestructive inspection. Further, the coordinate monitoring of measuring points is performed in the wafer. In consequence, it is possible to determine the dimensions at the same position before and after processing.

Thus, the gate dimension inspection becomes possible during the in-line process. Therefore, the CD variation due to the change with time of the etching apparatus can also be immediately feedbacked to the etching apparatus.

Incidentally, in this embodiment, SF₆ was added in the ME1 step whereby no sidewall protective layer was formed. However, the trimming amount can also be controlled by using a Cl₂, HCl, or HBr gas, or the like as a base gas of a gas type, and appropriately selecting the amount of F-containing gas (SF₆, NF₃, or CF₄) to be added, and the RF bias. Also, it is possible to obtain the trimmed gate shape having verticality by using a gas type such as CHF3/SF6 gas. Further, trimming may be difficult to perform at a high dopant concentration portion immediately under the mask of p-poly-Si according to the doping amount of the gate electrode. However, by further subdividing the ME1, and setting another step in which the foregoing gas type is appropriated selected, it is possible to trim both p-and n-poly-Si without a difference in resulting shape therebetween.

The UHR-ECR plasma etching apparatus was used for the formation of the I-type gate. However, in the present invention, the selection of the gas species is the principal matter. Therefore, even if an etching apparatus having other plasma source such as an ICP or CCP source is used, the control method is basically the same.

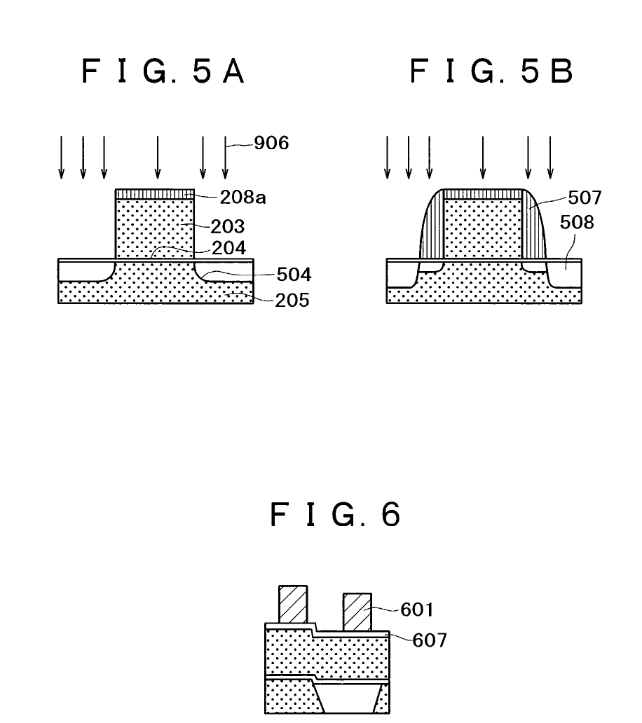

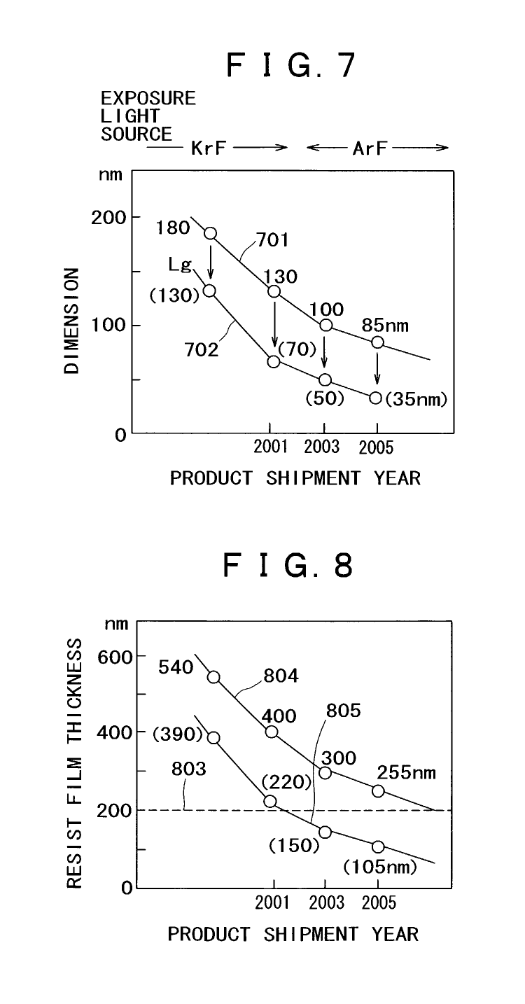

After formation of the I-type gate, a source/drain formation step is performed in the following manner. Schematically, as shown in FIG. 5A, prescribed impurity ions are implanted by using the gate electrode (203) itself as a mask to form a low-concentration diffusion layer 504. Subsequently, as shown in FIG. 5B, a sidewall spacer 507 is formed by deposition and etching. Then, the prescribed impurity ions are implanted as indicated by arrows, thereby to form a high-concentration diffusion layer 508.

(Embodiment 2)

A modified example of Embodiment 1 will be described below.

A gate was processed in cross sectional profile shown in FIG. 2D by the ME1 step in Embodiment 1. Then, also in the ME2 step, O₂ was not added, and the end point was determined by a HCL gas. No addition of O₂ results in the state in which no sidewall protective film 212 is formed in FIGS. 2E and 2F. The diagrams in this state are omitted.

Thereafter, spontaneous etching was effected with a HCl gas and at a Rf bias of 0 W (zeroWatt) for 50 sec, resulting in the trimmed gate shape shown in FIG. 2G.

In accordance with this embodiment, it is possible to further trim the sidewall of the gate electrode without forming a sidewall protective film by employing spontaneous etching by HCl.

In accordance with this embodiment, 50 sec was taken for 50-nm trimming. However, it is known that the trimming amount by HCl is proportional to the time. Therefore, it is possible to perform any trimming by time control. After processing in this trimming step, if required, the OE (over etch) step is inserted, so that the etch residue 213 at the step portion as shown in FIG. 2E and the like can be removed.

Incidentally, in another ME1 step subsequent to the ME1 step, selective etching was allowed to proceed at a processing pressure of 0.4 Pa with addition of 3% O₂. Then, the following experiment was carried out. The end point was determined in the ME2 step, and then the trimming step by HCl was inserted. In this case, the phenomenon could be observed that side etching was stopped due to the formation of the sidewall protective film. This indicates as follows. The trimming is inhibited due to the formation of the sidewall protective film unless etching is performed in a plasma atmosphere with an O₂ partial pressure of not more than 12 mPa (0.4 Pa×3%). To the end point determination method, the method is applied in which the property of the reaction product or the etchant to emit light in the plasma is utilized, and the change with time in the property is monitored.

Therefore, it has been shown that the O₂ partial pressure needs to be set at not more than 12 mPa as the condition for avoiding the formation of the sidewall protective film and allowing trimming to proceed.

Further, as another modified example of this embodiment, the poly-Si residual film amount 210 shown in FIG. 2D was determined by means of a film thickness interferometer. The process was switched from the ME1 step to a step of trimming the overall gate electrode side surface (RF bias: 0 w) at the time point when the poly-Si residual film amount 210 had reached 50 nm to 30 nm. The ion assisted reaction was inhibited due to spontaneous etching. As a result, it was possible to perform processing without causing the loss of the underlayer (gate insulating film) even when the gate insulating film 204 had been much reduced in thickness to about 1 nm.

In this embodiment, HCl was used for the trimming step. However, it has been shown as follows. Even if a H-containing halogen gas (HBr, HI), or a Cl or HBr gas added with a He-diluted H₂ gas or the like is used, the trimming effect is produced although the trimming rate is slowed.

In this embodiment, the UHF-ECR plasma etching apparatus shown in FIG. 3 is applied to the formation of the I-type gate as with Embodiment 1. However, even if an etching apparatus having other plasma source such as an ICP or CCP source is used, the control method is basically the same.

Further, by performing mask trimming and gate trimming in one processing chamber, or performing the trimming steps in combination with a method for performing vacuum transfer, it is also possible to trim the gate to a length of 50 nm from the exposure dimension of 180 nm of KrF or the like.

In Embodiments 1 and 2, there were respectively shown the cases in each of which a silicon dioxide film (SiO₂ film) was used as the gate insulating film. However, when an Al₂O₃ film, a Ta₂O₅ film, an oxinitride film, or a high dielectric film (high-k material) is adopted, it is possible to perform trimming by either of the methods of Embodiments 1 and 2.

(Embodiment 3)

Below, a description will be given to an embodiment on a method for controlling an I-type gate process when the mask proportion is different as compared with Embodiments 1 and 2.

In Embodiments 1 and 2, the mask proportion within the wafer (8-inch wafer) was 3%. However, the phenomenon was observed that the side etching was stopped at the central portion of the wafer due to an increase in mask proportion to 50%. This is presumably due to the following fact. The increase in mask proportion of a processing wafer results in a larger amount of O₂ supplied from the reaction products of the TEOS 208a and 208b serving as the hard mask at the wafer central portion.

Therefore, the reduction in etching rate of the mask, the reduction in dwell time, or the reduction in proportion of the composition of the reaction product (i.e., the increase in proportion of the composition of the etchant) is required.

An efficient way to reduce the etching rate of the mask is to reduce the RF bias from 40 W to 10 W. The etching rate of the thermal oxide film in this case decreased from 35 nm/min to 23 nm/min.

On the other hand, the dwell time is expressed as t=(processing pressure)×(volume)/(gas flow rate). Therefore, the reduction in pressure, the reduction in volume, and the increase in gas flow rate result in the reduction in dwell time, which can reduce the phenomenon of stopping of side etching at the central portion. SF₆ may be increased in amount for increasing the proportion of the etchant composition. It is noted that the volume denotes the volume of the processing chamber of the etching apparatus.

By using the method for reducing the dwell time, and the method for increasing the etchant proportion, in combination with the step of reducing the RF bias, it is possible to provide adaptability to a wafer with a higher mask proportion of not more than 60%.

Specifically, with a sample having a mask proportion of 50%, it was possible to improve the phenomenon of stopping of trimming at the central part of the wafer in the following manner. Namely, in the ME1 step, the amount of SF₆ to be added was increased to 10%, the flow rate was 1.5-fold increased, and the RF bias was reduced to 10 W.

Further, as indicated from the foregoing results, by setting the thermal oxide film rate at not more than 35 nm/min, it is possible to form an I-type gate in a product wafer having a mask proportion of not less than 3%.

Then, even when the mask material is changed, it is possible to obtain a guideline by giving a consideration to the mask etching rate in the same manner. There was recognized the phenomenon that the trimmed sidewall undergoes surface roughening when the mask material is SiN. Presumably, N is generated as the reaction product from the mask. Then, in the ME2 step, 3% N₂ was added to examine the effect of N. As a result, there was confirmed the phenomenon that the surface roughness of the sidewall was increased. Therefore, the sidewall is presumably roughened aslo when the SiN rate is high under the conditions of the ME1. The SiN etching rate under the conditions of Cl₂ added with 10% SF₆ and a RF of 10 W was determined, and found to be 51 nm/min. Then, a CF₄/HCl gas was used for reducing the etching rate. As a result, the SiN rate was reduced to 24 nm/min. Under this condition, it was possible to improve the sidewall surface roughness and achieve 100-nm trimming.

In this embodiment, the UHR-ECR plasma etching apparatus shown in FIG. 3 is used for the formation of the I-type gate as with Embodiment 1. However, even if an etching apparatus having other plasma source such as an ICP or CCP source is used, the control method is basically the same. However, in this process, the oxygen emitted from a quartz material from the chamber stops trimming. Therefore, when an ICP plasma whereby the electric field concentrates at the electromagnetic wave inlet window is used, it is necessary to select the conditions in which the window trimming rate is also controlled to not more than 30 nm/min. The wafer used in each of Embodiments 1 to 3 has a size of 8 inch. When the wafer has a size of 12 inch, it is possible to provide the adaptability thereto by 2.25-fold increasing the RF bias (making equal the outputs per unit area).

(Embodiment 4)

Below, a description will be given to an embodiment in which a transistor of a High-K (insulating film)/metal gate structure is formed. In this embodiment, the method of the present invention is applied to a damascene gate utilizing a dummy gate.

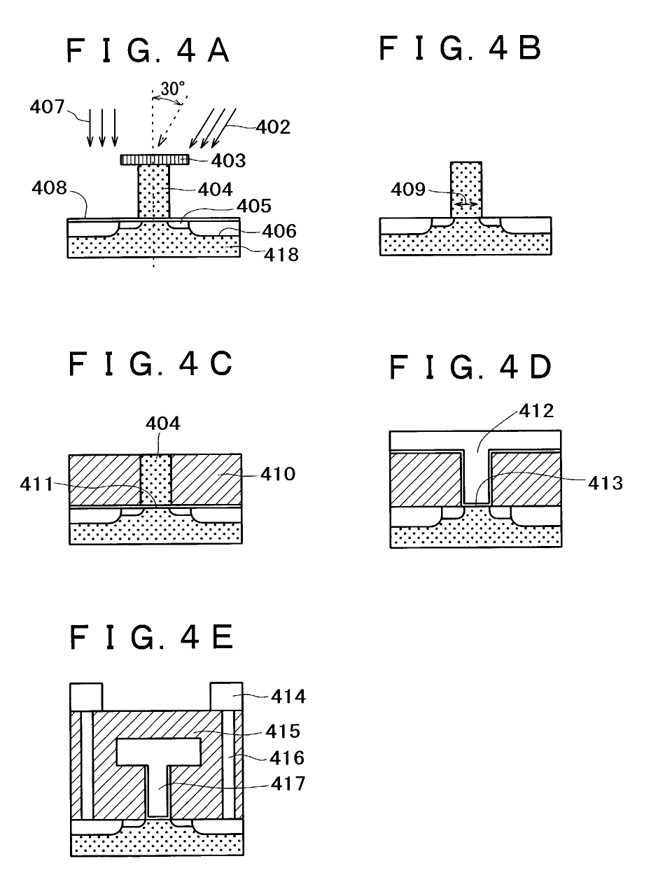

For example, on a P-type silicon substrate 418 of about 10¹⁷/cm³, an I-type dummy gate electrode 404 shown in FIG. 4A is formed by any of the methods of Embodiments 1 to 3. Thereafter, as shown in FIG. 4A, for example, arsenic ions are implanted with an implant energy of 40 keV and an implant dose of 2×10¹⁵/cm² vertically to the dummy gate electrode 404 as indicated by arrows 407 to form a high-concentration diffusion layer 406. Subsequently, for example, phosphorus ions are implanted with an implant energy of 20 keV and an implant dose of 2×10¹³/cm² into the wafer tilted at an angle of 30° to form a low-concentration diffusion layer 405. In FIG. 4A, the direction of implantation of phosphorus ions is indicated by arrows 402. It is noted that the gates included in the appended claims include the dummy gate.

After forming the I-type dummy gate electrode 404 in this manner, the angle of ion implantation is changed, which allows the formation of the high-concentration diffusion layer and the low-concentration diffusion layer in continuous steps without forming a spacer film.

Subsequently, cleaning is performed with a NH₄OH/H₂O₂ or HCl/H₂O₂ aqueous solution, or a HF solution to remove foreign matters and metal contaminants. Then, a stopper layer 408 and TEOS (hard mask) 403 made up of an oxide film are removed.

Subsequently, the dummy gate shown in FIG. 4B is subjected to dimension inspection for the gate length 409 by critical dimension scanning electron microscopy.

Then, an insulating layer 410 is deposited on the principal surface of the substrate 418. The insulating layer 410 is then subjected to a CMP processing (Chemical Mechanical Polishing). As a result, the surface of the dummy gate is exposed to obtain the cross sectional profile of FIG. 4C. Namely, there is provided a structure in which the dummy gate 404 is buried by the insulating layer 10.

Then, the dummy gate electrode 404 is etched back, or wet etched to a stopper layer 411, and then, the stopper layer 411 is removed by cleaning.

After the cleaning step, a high-k material 413 made of Ta₂O₅, Al₂O₃, and SiN is deposited, and a metal gate electrode material 412 such as W is deposited thereon (FIG. 4D). Thereafter, the metal gate electrode material 412 is etched to form a T-type metal gate 417.

Then, after deposition of an interlayer insulating layer 415, a contact plug 416 is formed on the source/drain, and a wiring layer 414 is formed, resulting in formation of the metal gate structure of FIG. 4E.

By utilizing the present invention, it is possible to form a gate having a length of not more than the exposure dimension. In addition, by using the I-type gate, it is possible to simultaneously form the high-concentration diffusion layer and the low-concentration diffusion layer by ion implantation. As a result, it becomes possible to shorten the process.

In this embodiment, the UHF-ECR plasma etching apparatus shown in FIG. 3 is applied to the formation of the I-type gate as with Embodiment 1. However, even if an etching apparatus having other plasma source such as an ICP or CCP source is used, the control method is basically the same.

Up to this point, the present invention completed by the present inventors was specifically described by way of the embodiments of the present invention. However, it is to be understood that the present invention is not limited to the embodiments, and that various changes and modifications may be made in the invention without departing from the spirit or scope thereof. Below, the specific examples will be shown.

(1) In Embodiment 1, the gate electrode trimming using a hard mask was described.

However, by preparing a wafer (sample) made up of a resist 601 and a mask structure of BARL 607 as shown in FIG. 6, it is possible to form an I-type gate by the same method as with the TEOS mask. In this case, the TEOS mask 208a and 208b shown in FIG. 2C is replaced with the BARL mask. Then, the BARL mask is patterned, and then the process goes to the step shown in FIG. 2D described in Embodiment 1. Incidentally, as shown in FIG. 6, the BARL 607 is an inorganic antireflection film formed by a CVD process, and the step of the STI 206 occurs as it is on the surface.

In accordance with the present invention, in processing of a fine gate in a length of narrower than or equal to the exposure limit, i.e., beyond the exposure limit, it is possible to form an I-type gate having a gate length of not more than 50 nm without a problem of an insufficient resist thickness. Particularly, it becomes possible to form an I-type gate trimmed along the overall side surface of the gate electrode with no underlayer loss and in a given trimming amount of about 0 to 150 nm. Therefore, it becomes possible to determine the gate processing dimension in an in-line process. As a result, it is possible to provide a method of manufacturing a semiconductor integrated circuit device, which is capable of improving the yield and throughput. Namely, when gate trimming necessary for processing the gate in a minute length of not more than the exposure dimension, it is possible to control the dimension without introducing another process flow and another dimension determination method. For this reason, it is possible to mass-produce the devices without reducing the total throughput, and in a high yield. Then, it is possible to prevent a rise in chip cost. Accordingly, it is possible to provide a low-priced semiconductor integrated circuit device to users. The foregoing invention has been described in terms of preferred embodiments. However, those skilled, in the art will recognize that many variations of such embodiments exist. Such variations are intended to be within the scope of the present invention and the appended claims.

What is claimed is:

1. A method of manufacturing a semiconductor integrated circuit device, comprising:
a step of depositing a gate material;
a step of transferring a circuit pattern onto a mask layer;
a gate electrode trimming step;
a cleaning step; and
a dimension inspection step,
wherein in the gate electrode trimming step, a gate electrode is trimmed along its side surface.

2. A method of manufacturing a semiconductor integrated circuit device, comprising:
a step of depositing a gate material on a gate insulating film;
a step of transferring a circuit pattern onto a mask layer;
a gate electrode trimming step;
a cleaning step; and
a dimension inspection step,
wherein in the gate electrode trimming step, the partial pressure of O₂ in a step of etching from immediately under a mask to the gate insulating film, or to a depth at the midpoint thereof is not more than 12 mPa.

3. A method of manufacturing a semiconductor integrated circuit device, comprising:
a step of depositing a gate material on a gate insulating film;
an exposure step of transferring a circuit pattern onto a mask layer;
a gate electrode trimming step;
a cleaning step; and
a dimension inspection step,
wherein in the gate electrode trimming step, the partial pressure of O₂ in a step of etching from immediately under a mask to the gate insulating film is not more than 12 mPa, and a step of subsequently trimming the gate electrode along its overall side surface with a gas containing H is further included.

4. The method of manufacturing a semiconductor integrated circuit device according to claim 1, wherein in a step of etching from immediately under a mask to a gate insulating film, or to a depth at the midpoint thereof, at least one of SF₆, NF₃, CF₄, and HCI is employed.

5. The method of manufacturing a semiconductor integrated circuit device according to claim 3, wherein the gas containing at least H is HC1.

6. The method of manufacturing a semiconductor integrated circuit device according to claim 1, wherein the timing for switching to a step of trimming the gate electrode along its overall side surface with a gas containing H is determined based on the result of detection of the residual amount of a gate electrode film.

7. The method of manufacturing a semiconductor integrated circuit device according to claim 1, wherein the etching rate of a mask material in a step of etching from immediately under a mask to a gate insulating film is set to be not more than 35 nm/min.

8. A method of manufacturing a semiconductor integrated circuit device, having a step of patterning a gate, the step comprising: patterning a hard mask on the gate by a resist mask, and then removing the resist mask; and trimming the gate material side surface by using the hard mask under such dry etching conditions that the reaction product will not be left on the gate material side surface to form an I-type gate.

9. The method of manufacturing a semiconductor integrated circuit device according to claim 8, wherein as one of the dry etching conditions, an oxygen is not added to an etching gas.

10. The method of manufacturing a semiconductor integrated circuit device according to claim 8, wherein as one of the dry etching conditions, the partial pressure of O₂ in an etching gas is not more than 12 mPa.

11. The method of manufacturing a semiconductor integrated circuit device according to claim 8, wherein the gate material comprises poly-Si.

12. The method of manufacturing a semiconductor integrated circuit device according to claim 8, wherein the hard mask is made up of an inorganic insulating film.

13. The method of manufacturing a semiconductor integrated circuit device according to claim 12, wherein the inorganic insulating film is made up of a SiO₂ film or a SiN film.

14. A method of manufacturing a semiconductor integrated circuit device, comprising:
a step of forming a gate film on a gate insulating film;
a step of forming a film to be a mask on the gate film;
a step of forming a photoresist layer on the film to be a mask;
an exposure step of transferring a circuit pattern onto the photoresist layer;
a step of transferring the transferred circuit pattern on the photoresist layer onto the film to be a mask, thereby forming a mask;
a step of removing the photoresist layer subjected to transfer;
a step of subsequently selectively etching the gate film from immediately under the mask to the gate insulating film, or to a depth at a midpoint thereof in a plasma atmosphere in which the partial pressure of O₂ is not more than 12 mPa;
a step of subsequently cleaning a gate electrode formed by the etching; and
an inspection step of determining the dimension of the gate electrode from above the gate electrode.

15. The method of manufacturing a semiconductor integrated circuit device according to claim 14, wherein the gate material comprises poly-Si.

16. The method of manufacturing a semiconductor integrated circuit device according to claim 14, wherein the hard mask is made up of an inorganic insulating film.

17. The method of manufacturing a semiconductor integrated circuit device according to claim 14, wherein the inorganic insulating film is made up of a SiO₂ film or a SiN film.
